(19) United States
(12) Patent Application Publication
(10) Pub. No.: US 2003/0006010 A1
(43) Pub. Date: Jan. 9, 2003

(54) Support apparatus for a wafer

(76) Inventors: Jens Holzbecher, Senftenberg (DE); Tina Kockritz, Weixdorf (DE); Steffen Topper, Dresden (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 10/186,969

(22) Filed: Jul. 1, 2002

(30) Foreign Application Priority Data
Jun. 29, 2001 (DE) 101 31 673.9

(51) Int. Cl. C23F 1/00; C23C 16/00

(52) U.S. Cl. 156/345.54; 156/345.51; 118/728; 118/729

(57) ABSTRACT

For effecting a uniform temperature distribution in a wafer in a process chamber, a support apparatus for a wafer is disclosed, comprising support means for supporting the wafer, temperature homogenization means arranged peripherally regarding to the wafer to provide a uniform thermal environment for the wafer, temperature homogenization means consisting of a plurality of segments, at least one of the plurality of segments being movable with regard to the other segments to enable supply and removal of the wafer to and from support means. By the fact that the at least one segment is movable with regard to the other segments, it can be elevated when introducing the wafer and can then be lowered during a process step at the wafer such that temperature homogenization means provides a uniform thermal environment for the wafer. Thereby it is made sure that in material depositioning processes an even layer thickness (uniformity) on the wafer will be achieved.

### BACKGROUND OF THE INVENTION

1. Field of the Invention

The present invention refers to a support apparatus for a wafer, which is mainly provided in a process chamber of a rapid thermal processing system.

2. Description of Prior Art

Wafer are thin flat disks out of a semiconductor crystal for the production of integrated circuits. For this purpose, certain material layers are disposed on the wafer surface in several process steps and then structured in several masking, etch and doping steps to generate the desired circuits. Some of the layers have to be subject to a so-called annealing process of the lattice structures afterwards. Such a treatment of material layers on the wafer surface is carried out in process chambers of RTP-systems, such as the SHS 2800 of Steag AST (now: Mattson). With RTP-systems, high temperature processes can be limited to a very short time span.

FIG. 1 shows a schematic cross section view of a process chamber of the above mentioned RTP system. The actual process chamber (“tube”) 2, consisting of quartz glass, for example, has an inlet for fluids on its right side. A front or press plate 6 is provided on the left side of the process chamber 2, having an opening 8 leading to an interior 10 of process chamber 2. Further, a chamber door 12 is provided serving for closing the opening 8 and thus the process chamber 2. Specific lamps 14 are provided at the top and bottom sides of the process chamber 2, enabling heating up of the chamber interior 10 or a wafer 22 in there, respectively, to process temperature in shortest possible time. A support apparatus 20 is provided in the chamber interior 10, whereon a wafer 22 is supported via support elements provided therefore.

As can be seen in FIG. 2, illustrating a top view of the wafer support apparatus 20, wherein process chamber 2 and chamber door 12 are omitted, the wafer 22 is carried by support means 20 at three contact points 24. Peripheral to wafer 22, a temperature homogenization means is provided in form of a so-called slip guard ring 26 divided into two levels, consisting of four segments each.

As can be seen best in the perspective view in FIG. 3, the upper level of the slip guard ring 26 has three segments on the side facing way from the front plate 6, lying in one level, and one segment 27 on the side facing the front plate 6, which is fixedly disposed in an elevated way to enable supply or delivery and removal of the wafer 22 from the wafer support apparatus or wafer tray 20, respectively. As can further be seen in FIG. 3, the three segments 26 of the upper level facing away from the front plate 6 are on one level with wafer 22. The four segments of the lower level are arranged in one level and are below the four segments of the upper level. Both the segments of the upper and lower levels are supported by support arms 28, attached to a frame part 30 of support apparatus 20. The totality of support means 20 (including support arms 28) and slip guard ring 26 is referred to as support apparatus (also wafer tray).

In the following, the method for removal of the wafer from the wafer support means 20 will be discussed with reference to FIG. 1. As can be seen at the left portion of the figure, a wafer handling means 34, a so-called end effector of a robot, is introduced with opended chamber door 12 into opening 8 into the process chamber interior 10 in the direction of arrow 32. The end effector 34 will then be moved under the wafer 22 up to the end of arrow 32, where a front portion of the end effector 34 is fixed to the wafer 22, for example via a suction means (not shown). As soon as the area of the end effector 34 and the wafer 22 touch, a vacuum builds up, holding the wafer 22 at the end effector 34 when the robot is moving. Afterwards, the end effector 34 raises the wafer 22 by a small amount, so that it is in a position above the three segments of the upper level of the slip guard ring 26, and finally moves the wafer 22 below the elevatedly disposed segment 27 in direction of arrow 36 through opening 8 out of the process chamber interior 10. Thereupon, wafer 22 is usually inserted into a storage cassette (not shown) predetermined for that, to be taken out of it for a subsequent processing step. Inserting the wafer 22 proceeds in an analogous way in reverse order.

If there is a wafer 22 in the interior 10 of process chamber 2, chamber door 12 (see FIG. 1) is moved up to seal the process chamber interior 10. After that, the processing procedure, for example depositing of a layer, will be started. As has been noted with reference to FIG. 3, the segment 27 of the upper level of the slip guard ring 26 facing the front plate 6 is disposed elevatedly regarding to the level where the wafer 22 and the other three segments of the lower level are disposed. Since the slip guard ring 26 serves to supply heat to wafer 22, it can be seen that by a raised storage of the segment 27 in the area of the wafer 22 adjacent to this segment a temperature variation to the other areas of the wafer 22 occurs, which are adjacent to the three segments of the slip guard ring facing away from the front plate 6. As a result, an uneven layer thickness occurs due to temperature variation in the area 23 of the wafer adjacent to segment 27, for example in a process step of depositing a material layer on wafer 22, such as is shown in FIG. 2.

Especially with a plurality of process steps, this unevenness adds up to a no longer acceptable amount in the layer thickness on the side adjacent to segment 27. Therefore it is, for example with photolitographic processes, no longer possible to focus this area 23 of the largest layer thickness deviation (“range deviation”) on the wafer, which leads to yield losses in area 23.

### SUMMARY OF THE INVENTION

It is therefore the object of the present invention to provide a support apparatus for a wafer, especially for usage in a process chamber, where a uniform thermal environment i-s provided for the wafer.

In accordance with a first aspect of the invention this object is achieved by a support apparatus for a wafer comprising a support means for supporting the wafer and a temperature homogenization means, disposed peripherally regarding the wafer to provide a uniform thermal environment for the wafer, the temperature homogenization means consisting of a plurality of segments, at least one of the plurality of segments being movable regarding to the other segments to enable supply and removal of the wafer to and from support means. In contrary to the prior art, where the segment of temperature homogenization means facing the front plate was disposed fixedly elevated to enable the supply and removal of the wafer to and from the support means, the inventive means allows that at least one segment of the plurality of segments of the temperature homogenization means is movable or riseable during supply and removal of the wafer to and from support means, and can be moved back, with the wafer inserted in support means, into a position where the temperature homogenization means can provide a uniform thermal environment to the wafer.

According to an advantageous embodiment of the invention, the plurality of segments of the temperature homogenization means form one level, the at least one segment being movable regarding to the other segments from the level during supply and removal of the wafer. For providing an optimized uniform heat supply it is advantageous to arrange the plurality of segments of the temperature homogenization means in one level with the wafer. Further, the individual segments of the plurality of segments can be portions of a ring, forming together a ring-shaped temperature homogenization means, a so-called slip guard ring.

According to another advantageous embodiment, the inventive support apparatus comprises a lifting or elevating means for moving the at least one segment of the temperature homogenization means. The lifting means can be built in form of a lifting or elevating fork, comprising a frame part with a portion where a plurality of support arms are provided that engage at predetermined locations of the at least one movable segment of the temperature homogenization means. Thereby it is possible, that projection portions are formed at the support arms, engaging predetermined recessions of the one movable segment of the temperature homogenization means. This lifting fork can then be activated by an electrical or mechanical means. Mechanical means can especially comprise a pneumatic liftinging cylinder and a pneumatic linear unit, respectively. Advantageously, support means of the inventive support apparatus is made of quartz glass.

According to another advantageous embodiment, the inventive support apparatus further comprises second temperature homogenization means arranged peripherally regarding to the wafer below the first temperature homogenization means. This second temperature homogenization means can therefore consist of a plurality of segments, like first temperature homogenization means. The segments of respective temperature homogenization means can thereby consist of silicon.

According to another aspect, the present invention provides a process chamber for treating a wafer comprising a process area where a support apparatus for a wafer is provided, as defined above. Advantageously, the process chamber further comprises a chamber door for opening and closing the process chamber, the at least one moveable segment of temperature homogenization means of the support apparatus being moved depending on the opening state of the chamber door. This means, the moving of the one movable segment of temperature homogenization means, i.e. raising and lowering the segment, can-be controlled automatically in accordance with a door opening signal. Thereby it is possible, that with opened chamber door the at least one movable segment of the temperature homogenization means can be moved into a position where a wafer can be supplied to or removed from the support means, and is, with closed chamber door, moved into a position where temperature homogenization means surrounds the wafer evenly.

### BRIEF DESCRIPTION OF THE DRAWINGS

Preferred embodiments of the present invention will be discussed in more detail with reference to the accompanying drawings. They show:

FIG. 1 a cross sectional view of a process chamber arrangement of the prior art, taken along line A-A of FIG. 2;

FIG. 2 a top view of a support apparatus arranged in a process chamber of the prior art, where, in contrary to FIG. 1, process chamber walls, heating means and heating elements, respectively, and chamber door are omitted;

FIG. 3 a perspective view from the side and from the top of the support apparatus of the prior art shown in FIG. 2;

FIG. 4 a perspective view from the side and from the top of support means of the inventive support apparatus;

FIG. 5 a top view of a movable segment of temperature homogenization means of the inventive support apparatus;

FIG. 6 a lifting fork for engagement with the movable segment shown in FIG. 5

FIG. 7 a perspective view of a back side of a front plate of a RTP-system furnace where the inventive support apparatus is provided, the walls of the process chamber arranged around the support apparatus as well as heating means and chamber door being omitted; and

FIG. 8 a front side of the front plate illustrated in FIG. 7 with the inventive support apparatus, wherein also the walls of the process chamber surrounding the support apparatus as well as heating means and chamber door are omitted.

### DESCRIPTION OF PREFERRED EMBODIMENTS

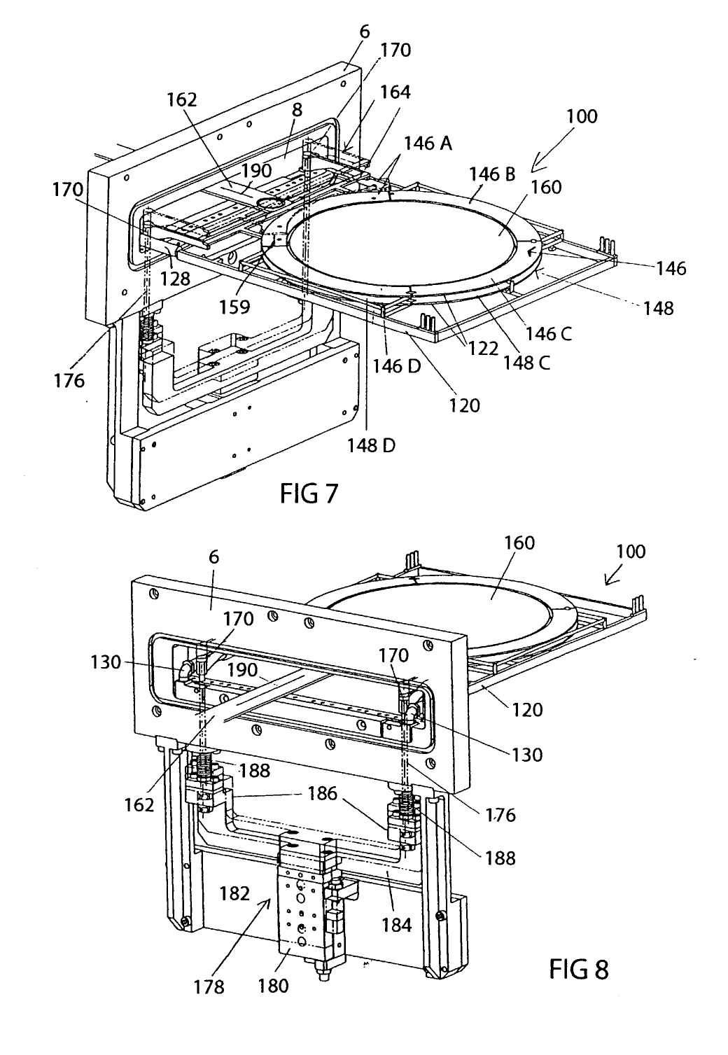

For the illustration of an embodiment of the inventive support apparatus, reference is first made to FIG. 7, where the inventive support apparatus 100, consisting mainly of support means (“wafer tray”) 120 and temperature homogenization means (“slip guard ring”) 122 is shown in an assembly representation.

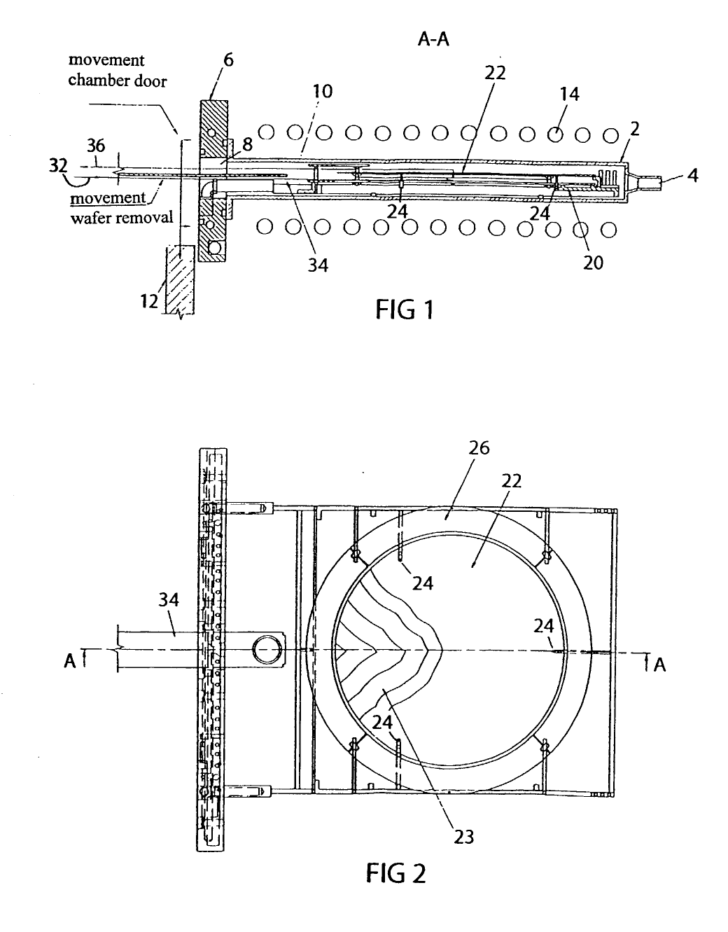

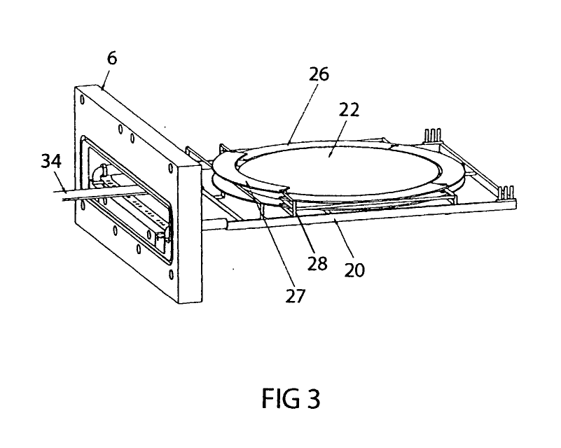

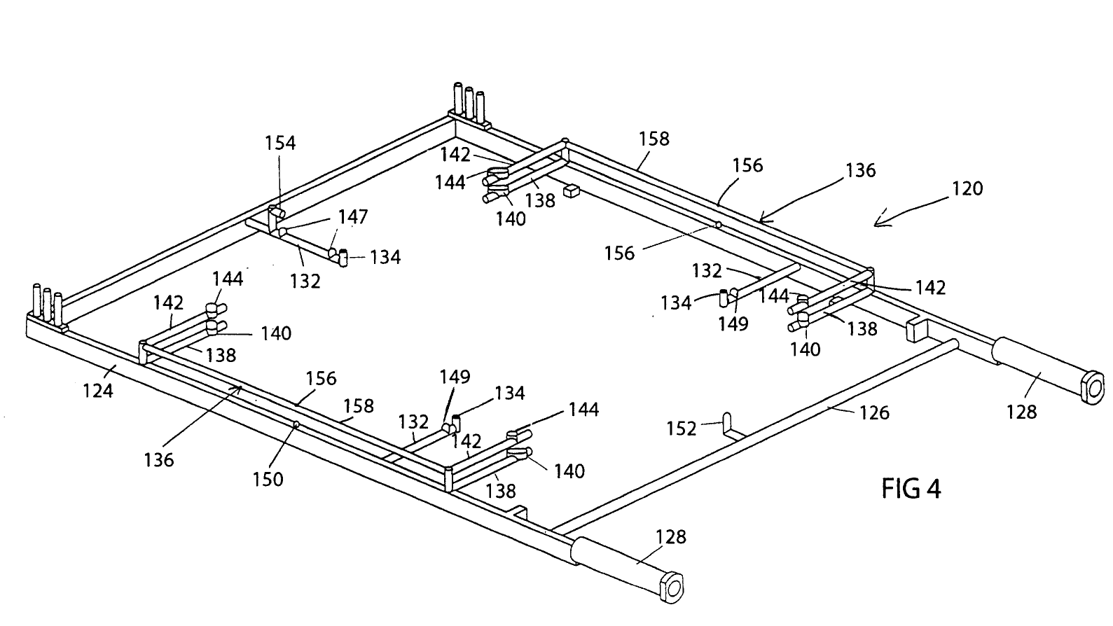

As it is shown in more detail in FIG. 4, support means 120 preferably consists of quartz glass and has an U-shaped frame 124 at whose portion shown on the right side in the Figure a strut 126 is provided. Further, on this portion illustrated at the right side, fixing elements 128 are provided, that are attached to the back side of the front plate of an RTP-system furnace at connecting portions 130, as shown in FIGS. 7 and 8, to hold the support apparatus 100 in the process chamber (corresponding to FIG. 1, where the support apparatus of the prior art is shown in an inserted state).

Support means 120 further has three support arms 132, at whose side facing away from the frame portion 124 respective contact portions 134 are provided, on which a wafer 160 can be disposed via plugged-in pins, as it is shown in FIG. 7. Above that, the frame part 124 has support arrangements 136 having lower support arms with lower centering portions 140 and upper support arms 124 with upper centering portions 144. The support arrangements 136 make it possible to attach the temperature homogenization means 122 (see FIG. 7) consisting of a ring of a lower level and an upper ring 146, respectively, with segments 146a-146d, and a ring of a lower level and a lower ring 148, respectively, with segments 148a-148d in an exact way with regard to position on support means 120.

As can be seen in FIG. 7, the upper 146 and lower ring 148 of temperature homogenization means 122 are divided into four segments each. Starting from the segment on the side of the ring facing the front plate 6, the individual ring segments are to be designated with the letters a, b, c, d in the clockwise direction, even when some segments of the lower ring 148 can not be seen in the Figure. The individual segments 146a to 146d and 148a to 148d are preferably made of silicon.

First, reference is made to the lower ring 148, whose segments 148a to 148d are arranged in one level. As can be seen in FIG. 4, in connection with FIG. 7, the segment 148c facing away from the front plate 6 is supported by portions of the support arms 138 as well as by projection portions 147 of the support arms 132 and held in position by the lower centering portions 140. The segments 148b and 148d are also supported by portions of the lower support arms 138 as well as by projection portions 149 of the support arms 132 and by projection portions 150 of the frame part 124 and held in position by the lower centering portions 140. The segment 148a is supported by portions of the lower support arms 138 as well as by a support portion 152 of the strut 126 and held in position by respective lower centering portions 140.

Reference is now made to the upper ring 146, whose segments 146b to 146d are supported in one level rigidly above the segments 148b to 148d. The segment 146c is thereby supported by portions of the support arms 142 as well as by a support portion 154 of the support arm 132 and held in position by respective upper centering portions 144. The segments 146b and 146d are also supported by portions of the upper support arms 142 as well as by projections 156 at an upper strut 158 of a respective support arrangement 136 and held in position by respective upper centering portions 144.

In contrary to the prior art, the segment 146a facing the front plate 6 is not arranged rigidly above the level formed by segments 146b to 146d, to enable supply and removal of a wafer, respectively, to and from the support means 120, respectively, but is movably arranged, as it is particularly illustrated by arrow 159 in FIG. 7.

This movement of segment 146a, as well as the movement mechanism belonging to it will now be discussed. As it is shown in FIG. 7 by continuous lines, the movable segment 146a is in one level with the other segments 146 to 146d of the upper ring 146, when a wafer 160 has been inserted into the inventive support apparatus 100 for treatment and processing, respectively,. More specifically, in this state the wafer 160 rests on the contact portions 134 of the plugged-in pins of the support arms 132 (see FIG. 4) and is surrounded along its periphery by rings 146 and 148 of temperature homogenization means 122. To provide a thermal surrounding for wafer 160 that is as uniform as possible, all segments, including segment 146a of the upper ring 146, are, in contrary to the prior art, in one level with regard to each other and are preferably in one level with wafer 160. Below the wafer 160 is a so-called hotliner, i.e., a wafer with three bores, surrounded by the lower slip guard ring 148.

The slip guard rings 146, 148 serve for the prevention of thermal differences in the margin area of the so-called hotliner, upon which the actual product wafer 160 rests. Such thermal differences would occur without the slip guard rings 146, 148, due to the so-called “photon box effect” and the edge effect. The so-called “photon box effect” occurs during the heat up procedure and causes the edges of the wafer to be hotter than its center. During the steady state the edge effect occurs, which means that the edges of the wafer are colder than its center.

In contrary to the prior art, the rings 146 and 148 prevent that temperature variations or temperature deviations occur in wafer 160, that would lead to an uneven layer thickness or a “range deviation”, especially in material depositioning steps, as it has been discussed with reference to FIG. 2 regarding to area 23.

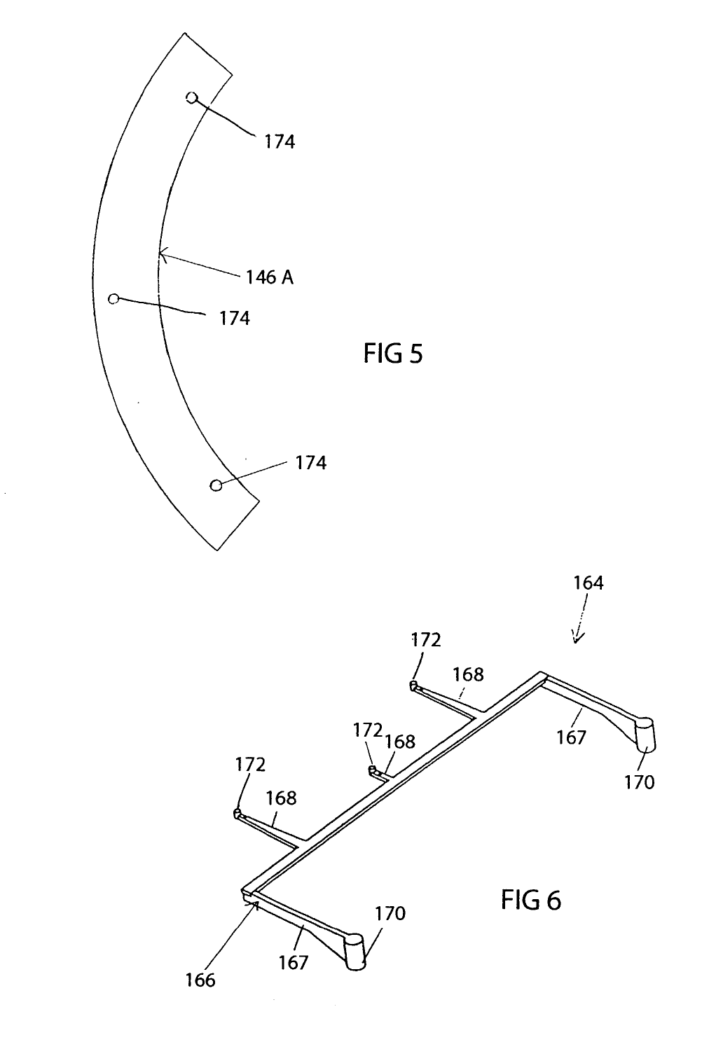

To be able to remove wafer 160 from support apparatus 100 after a processing step via robot handling means or robot end effector 162, it is necessary that the movable segment 146a is moved out of the level with the other segments 146b to 146d, and the wafer 160, respectively. For that purpose, the segment 146a is positioned on a lifting fork 164, preferably made of quartz glass, by which the segment 146a can carry out a movement according to arrow 159 perpendicular to the level of the ring 146 (in FIG. 7 upwards). As it is illustrated in more detail in FIG. 6, lifting fork 164 consists of a mainly U-shaped frame part 166, at whose front portion three support arms 168 and at whose back portion at legs 167 respective mounting portions 170 are provided. The length of support arms 168 is dimensioned such that projection portions 172 provided on the end of support arms 168 facing away from the frame part 166 can engage with recessions 174 of the movable segment 146a as illustrated in a top view in FIG. 5. The mounting portions 170, however are attached at lifting rams 176 of a lifting apparatus 178.

As can be seen best in FIG. 8, lifting apparatus 178 has a pneumatic linear unit 180, which is disposed on the front plate 6 of the furnace of the RTP-system. It should be noted that instead of the pneumatic linear unit other mechanical or electrical drive means can be used as well. At the top of the pneumatic linear unit 180 a piston 182 protrudes, which is movable in the longitudinal direction of the pneumatic linear unit, i.e. upwards and downwards in the level of front plate 6. A mainly U-shaped support part 184 is attached to this piston 182, respective lifting rams 176 are attached at its upper leg portions 186. Thereby, the respective lifting rams 176 are surrounded by a membrane bellows 188 across a certain distance, starting from the upper leg portions, to provide a sealed feed-through for the lifting ram 176.

In FIGS. 7 and 8, a lower position is illustrated by continuous lines, where all parts of lifting apparatus 178 including lifting ram 176 as well as lifting fork 164 are lowered such that the movable segment 146a is in one level with the other segments 146b to 146d, as it is requested during a processing step and a process step, respectively. The dash-dotted lines, however, show an upper state, where lifting means 178 including lifting ram 176 and lifting fork 164, are risen such that the movable segment 146a is above the level of the upper ring 146 by a predetermined amount (in the practical embodiment about 8 mm). This state, corresponding essentially to the state shown in FIG. 1, makes it possible that a robot end effector 162 moves in the direction of arrow 190 in a position below wafer 160, fixes it by sucking at its end portion, raises it slightly above the level of segments 146b to 146d and removes it from the process chamber through the opening 8 of the front plate. It should be noted that the legs 167 of the frame part 166 of the lifting fork 164 are spaced that far apart from each other that it is possible to move the wafer 160 between them for supply and removal, respectively.

After removing the wafer 160, a new wafer can be inserted by the robot end effector 162 in respective reverse order into the process chamber and the support apparatus 100 in it, respectively. Like in the process of removing the wafer 160, when inserting the wafer the lifting apparatus 178 including the lifting ram 176 and lifting fork 164 is also in an upper position, to enable moving the wafer 160 into the upper ring 146 via the robot end effector 162. After the wafer has been placed on the contact portions 134 of support means 120, end effector 162 will be disengaged from the wafer and moves out of the process chamber in the direction of arrow 190. To provide again a uniform and homogenous thermal environment for the wafer 160, respectively, the lifting apparatus 178 including lifting 176 and lifting fork 164 is brought into a lower position, so that the movable segment 146a is lowered into a position where it is in one level with the other segments 146b to 146d and the wafer 160. As soon as the chamber door 12 (see FIG. 1) closes process chamber 2, treatment and processing, respectively, of the wafer can begin.

According to another embodiment of the present invention it is possible to control the movement and the activation of the lifting apparatus 178, respectively, automatically depending on the position of the chamber door 12. The lifting apparatus 178 is, for example, directed to take up an upper position where the movable segment 146a is above the level of segments 146b to 156d, when the chamber door is in a position where the opening of the front plate is not covered by it and the process chamber is opened, respectively. Consequently, the lifting apparatus 178 is directed to take up a lower position where the movable segment 146a is in one level with the other segments 146b to 146d of ring 146 when the chamber door 12 covers opening 8 and thus closes the process chamber to carry out a processing step and a process step, respectively, at a wafer 160.

This way it is automatically made sure that the segments of the respective rings 146 and 148 are in one level, respectively, to obtain the already described homogenization of the temperature distribution on the wafer.

### REFERENCE NUMBER LIST

2 process chamber

4 inlet

6 front plate

8 opening

10 process chamber interior

12 chamber door

14 heating elements

20 support means

22 wafer

23 area of uneven layer thickness

24 contact points

26 heat transfer means/slip guard ring

27 fixed elevatedstored segment

28 support arms

30 frame part

32 arrow direction into 10

34 robot end effector

36 arrow direction out of 10

100 support apparatus

120 support means

122 heat transfer means/slip guard ring

124 O-shaped frame part of 120

126 strut for stabilizing 124

128 mounting end portion

130 connecting portions for attaching 128

132 support arms for 134

134 contact portions

136 support arrangements

138 lower support arms for 140

140 lower centering portions

142 upper support arms for 144

144 upper centering portions

146 upper ring

147 protection portions for 148c

148 lower ring

149 projection portions for 148b, d

150 projection portions at 124

152 support portion of 126

154 support portion of 132

156 projections at 158

158 upper strut of 136

159 arrow direction of the movement of 146a

160 wafer

162 end effector

164 lifting fork

166 U-shaped frame part of 164

167 leg of 166

168 support arms to 166

170 mounting portions

172 projection portions of 168

174 recessions at 164a

176 lifting ram

178 lifting apparatus

180 pneumatic linear unit

182 piston to 180

184 U-shaped support part

186 upper leg portions of 184

188 membrane bellows

190 arrow direction into/out of process chamber

What is claimed is:

1. A support apparatus for a wafer, comprising:
support means for supporting said wafer;
temperature homogenization means, arranged peripherally regarding said wafer to provide a uniform thermal environment for the wafer;
temperature homogenization means consisting of a plurality of segments; and
at least one of the plurality of segments being movable with regard to the other segments to enable supply and removal of the wafer to and from support means.

2. The support apparatus according to claim 1, wherein the plurality of segments form one level, the at least one of the plurality of segments being movable from the level.

3. The support apparatus according to claim 2, wherein the plurality of segments is arranged in one level with the wafer.

4. The support apparatus according to claim 2, wherein the individual segments of the plurality of segments are portions of a ring, the portions together forming a ring-shaped temperature homogenization means.

5. The support apparatus according to claim 1, further comprising lifting means for moving the at least one segment.

6. The support apparatus according to claim 5, wherein said lifting means comprises a lifting fork including a frame part having a plurality of support arms provided thereto, that engage at predetermined positions of the at least one segment.

7. The support apparatus according to claim 5, further comprising electrical or mechanical means for activating said lifting means.

8. The support apparatus according to claim 7, wherein said mechanical means is a pneumatic linear unit.

9. The support apparatus according to claim 1, wherein said support means consists of quartz glass.

10. The support apparatus according to claim 1, further comprising a second temperature homogenization means consisting of a plurality of segments which is arranged peripherally regarding to the wafer below said temperature homogenization means.

11. The support apparatus according to claim 1, wherein the segments of respective temperature homogenization means are made of silicon.

12. A process chamber arrangement for treating a wafer, having a process area in which a support apparatus for a wafer according to claim 1 is provided.

13. The process chamber arrangement according to claim 12, further comprising a chamber door for opening and closing the process chamber, wherein the at least one movable segment of the support apparatus is activated in dependency of the opening state of the chamber door.
